(19) United States
(12) Patent Application Publication
(10) Pub. No.: US 2026/0255583 A1
(43) Pub. Date: Aug. 27, 2026

(54) MEMORY STRUCTURE AND MANUFACTURING METHOD THEREOF

(71) Applicant: Winbond Electronics Corp., Taichung City (TW)

(72) Inventors: Wei-Zhi Fang, Tainan City (TW); Shu-Ming Li, Kaohsiung City (TW)

(73) Assignee: Winbond Electronics Corp., Taichung City (TW)

(21) Appl. No.: 19/463,152

(22) Filed: Jan. 29, 2026

(30) Foreign Application Priority Data
Feb. 21, 2025 (TW) 114106427

(51) Int. Cl. H10B 12/00

(52) U.S. Cl. CPC H10B 12/485; H10B 12/02; H10B 12/482

(57) ABSTRACT

A memory structure including a substrate, a lower barrier layer, a bit line contact window, and a bit line structure. The substrate includes multiple active regions. The lower barrier layer is disposed on the substrate, and overlaps with one of the active regions in a top view direction of the substrate. The bit line contact window is disposed on the lower barrier layer, and is electrically connected to one of the active regions. The bit line structure is formed above the substrate and disposed on the bit line contact window, and includes an upper barrier layer, a bit line layer, a top cover layer, and a first liner layer.

### CROSS-REFERENCE TO RELATED APPLICATION

This application claims the priority benefit of Taiwan application serial no. 114106427, filed on Feb. 21, 2025. The entirety of the above-mentioned patent application is hereby incorporated by reference herein and made a part of this specification.

### BACKGROUND

### Technical Field

This disclosure relates to a memory structure and a manufacturing method thereof, and particularly relates to a dynamic random-access memory and a manufacturing method thereof.

### Description of Related Art

As the size of dynamic random-access memory (DRAM) gradually decreases, the correspondingly increased capacitive load and/or impedance value brings challenges to the operation of dynamic random-access memory. Specifically, the increase in capacitive load and/or impedance value will increase the resistance-capacitance delay time (RC-delay), which will reduce the operating speed and/or operating performance of the dynamic random-access memory.

### SUMMARY

An embodiment of this disclosure provides a memory structure, which includes a substrate, a bottom barrier layer, a bit line contact window, and a bit line structure. The substrate includes multiple active regions. The bottom barrier layer is disposed on the substrate and overlaps with one of the active regions in a top view direction of the substrate. The bit line contact window is formed above the substrate and disposed on the bottom barrier layer, and is electrically connected with one of the active regions. The bit line structure is disposed on the bit line contact window and includes a top barrier layer, a bit line layer, a top cover layer, and a first liner layer. The bit line layer is disposed on the top barrier layer. The top cover layer is disposed on the bit line layer. The first liner layer is disposed on the top barrier layer, the bit line layer, and sidewalls of the top cover layer. A material of the bit line contact window includes tungsten, and a material of the first liner layer includes oxide.

An embodiment of this disclosure provides a manufacturing method of a memory structure, which includes the following. A stack material layer is formed on a substrate. The stack material layer includes a bottom barrier material layer, a bit line contact window material layer, a top barrier material layer, a bit line material layer, and a top cover material layer stacked in sequence. A patterning process and an oxide layer growth process are performed on the stack material layer to form multiple bit line structures, a bit line contact window, and a bottom barrier layer. One of the bit line structures includes a top barrier layer, a bit line layer, and a top cover layer stacked in sequence, and includes a first liner layer disposed on the top barrier layer, the bit line layer, and sidewalls of the top cover layer. Multiple contact window openings are formed.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1C illustrate cross-sectional schematic views of a manufacturing method of a memory structure according to an embodiment of this disclosure.

FIG. 2A to FIG. 2C illustrate cross-sectional schematic views of a manufacturing method of a bit line structure according to an embodiment in FIG. 1B.

FIG. 3A to FIG. 3C illustrate cross-sectional schematic views of a manufacturing method of a bit line structure according to another embodiment in FIG. 1B.

### DESCRIPTION OF THE EMBODIMENTS

The following exemplifies embodiments and explains them in detail with reference to the accompanying drawings, but the provided embodiments are not intended to limit the scope covered by this disclosure. Moreover, the figures are for illustrative purposes only and are not drawn to scale. For ease of understanding, in the following description, the same elements will be explained using the same symbols.

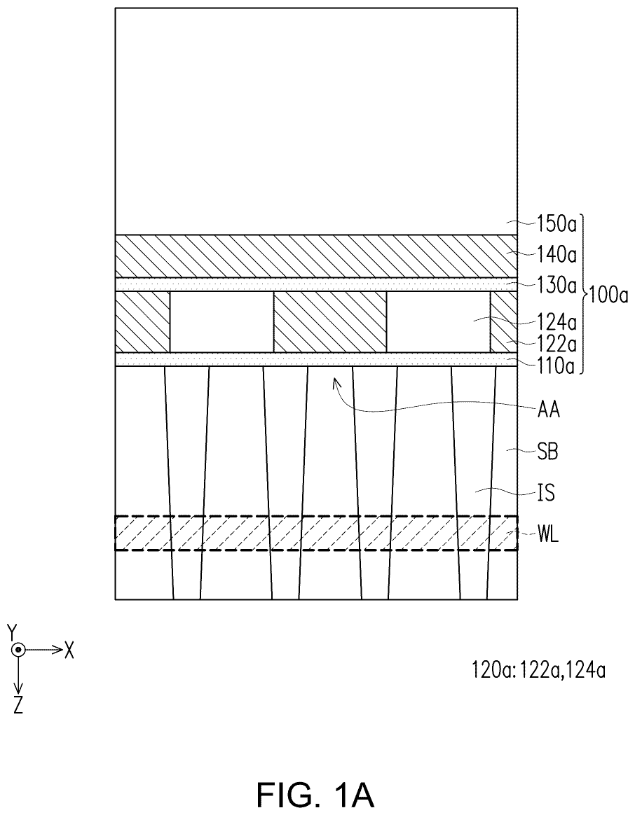

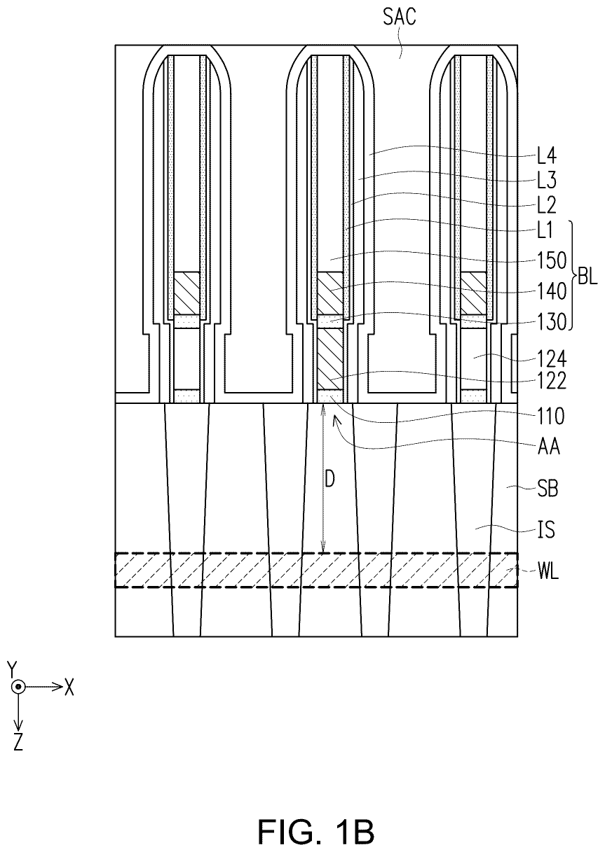

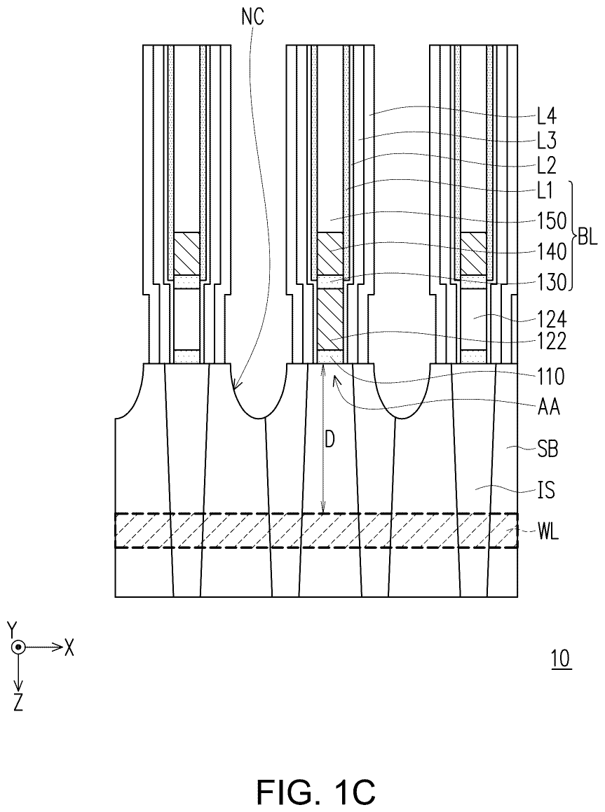

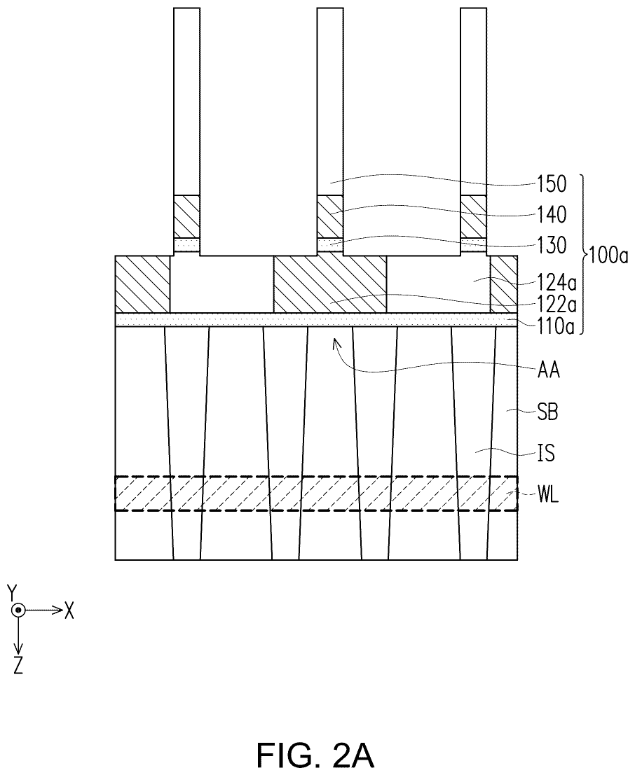

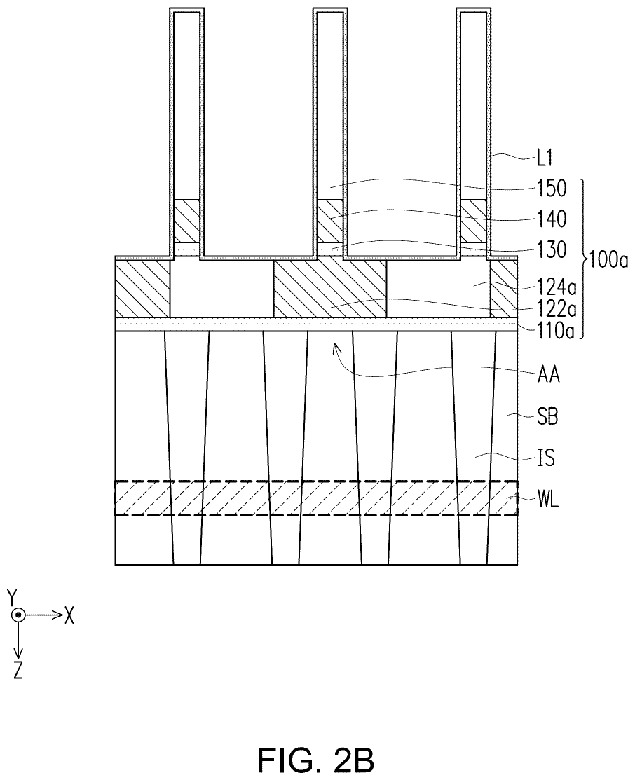

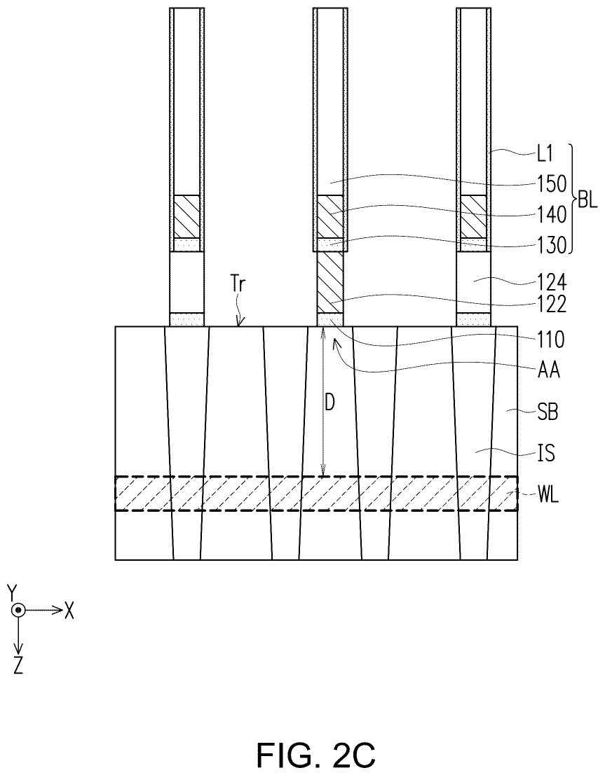

FIG. 1A to FIG. 1C illustrate cross-sectional schematic views of a manufacturing method of a memory structure according to an embodiment of this disclosure, and FIG. 2A to FIG. 2C illustrate cross-sectional schematic views of a manufacturing method of a bit line structure according to an embodiment in FIG. 1B.

Please refer to FIG. 1A. First, a stack material layer 100a is formed on a substrate SB. The substrate SB may be, for example, a semiconductor substrate. In one embodiment, the material of the substrate SB may include silicon, doped silicon, germanium, silicon-germanium, semiconductor compounds, other suitable semiconductor materials, or combinations thereof. For example, the substrate SB may be a silicon substrate.

The substrate SB may include multiple isolation structures IS, multiple active regions AA, and multiple embedded word lines WL. The isolation structures IS may be, for example, shallow trench isolation structures. The material of the isolation structures IS may be, for example, undoped silicon oxide, silicon nitride, or a combination thereof. One of the active regions AA may be located, for example, between adjacent isolation structures IS. In other words, the active regions AA may be defined by disposing the isolation structures IS. The embedded word lines WL may extend, for example, along direction X and may be arranged along direction Y.

The stack material layer 100a includes, in this order, a lower barrier material layer 110a, a bit line contact window material layer 120a, an upper barrier material layer 130a, a bit line material layer 140a, and a top cover material layer 150a, stacked in sequence, but this disclosure is not limited thereto. The bit line contact window material layer 120a may include multiple bit line contact window patterns 122a and multiple oxide patterns 124a, wherein one of the oxide patterns 124a is disposed between adjacent bit line contact window patterns 122a. In this embodiment, the bit line contact window material layer 120a may be formed by conducting the following steps.

First, a bit line contact window pattern material layer (not shown) is formed through a suitable deposition process. Next, multiple bit line contact window patterns 122a are formed by conducting an etching process on the bit line contact window pattern material layer. Afterwards, an oxide pattern material layer (not shown) is formed through a suitable deposition process, wherein the oxide pattern material layer at least fills in between adjacent bit line contact window patterns 122a. Then, multiple oxide patterns 124a are formed by conducting a planarization process on the oxide pattern material layer.

In this embodiment, the material of the lower barrier material layer 110a and the upper barrier material layer 130a may include metal, for example, titanium, titanium nitride, tantalum, tantalum nitride, or combinations thereof, and may be formed through a suitable deposition process. The material of the bit line contact window patterns 122a and the bit line material layer 140a may include metal, for example, tungsten, aluminum, copper, titanium, tantalum, tungsten, niobium, molybdenum, or combinations of the aforementioned. The material of the oxide patterns 124a may include oxide, for example, silicon oxide. The material of the top cover material layer 150a may include insulating material, for example, silicon nitride, and may be formed through a suitable deposition process.

Please refer to FIG. 1B. Next, a patterning process and an oxide layer growth process are conducted on the stack material layer 100a to form multiple bit line structures BL. In this embodiment, the bit line structures BL may be formed by conducting the steps as shown in FIG. 2A to FIG. 2C, but this disclosure is not limited thereto.

Please refer to FIG. 2A. An etching process is conducted to remove part of the top cover material layer 150a, part of the bit line material layer 140a, and part of the upper barrier material layer 130a, to form a top cover layer 150, a bit line layer 140, and an upper barrier layer 130. The bit line contact window material layer 120a may serve as an etching stop layer. In other words, after conducting this etching process, part of the bit line contact window material layer 120a may be exposed. In this embodiment, the etching process may simultaneously remove part of the bit line contact window material layer 120a.

Please refer to FIG. 2B. A plasma process is conducted to form a liner layer L1. In this embodiment, the liner layer L1 is formed on the sidewalls of the upper barrier layer 130, the bit line layer 140, and the top cover layer 150, and is formed on the surface of the exposed bit line contact window material layer 120a. The material of the liner layer L1 may include oxide, for example, silicon oxide. In one embodiment, the plasma process includes an in-situ plasma process, but this disclosure is not limited thereto.

Please refer to FIG. 2C. An etching process is conducted to remove part of the liner layer L1, part of the bit line contact window material layer 120a, and part of the lower barrier material layer 110a, to form the bit line structures BL, a bit line contact window 122, and a lower barrier layer 110, wherein the substrate SB may serve as an etching stop layer. As shown in FIG. 2C, each bit line structure BL includes, for example, an upper barrier layer 130, a bit line layer 140, and a top cover layer 150 stacked in sequence on the substrate SB, and includes a liner layer L1 disposed on the upper barrier layer 130, the bit line layer 140, and the sidewalls of the top cover layer 150. In this embodiment, the liner layer L1 may protect the upper barrier layer 130, the bit line layer 140, and the top cover layer 150 during this etching process, and after this etching process, a trench Tr exposing part of the substrate SB are formed. Additionally, in this embodiment, a lateral etching process may also be included to adjust the width of the bit line contact window 122, making it substantially the same as the width of the bit line layer 140. Furthermore, in one embodiment, this lateral etching process also removes part of the oxide pattern 124a, forming an oxide layer 124.

After individually forming the bit line contact window 122 and the lower barrier layer 110, a liner layer L2, a liner layer L3, a liner layer L4, and a sacrificial layer SAC may be formed in sequence on the substrate SB, forming the structure shown in FIG. 1B. Please refer to FIG. 1B. The liner layer L2 and the liner layer L3 may be conformally formed in sequence on the substrate SB through suitable deposition processes. Specifically, the liner layer L2 may cover the liner layer L1, the bit line contact window 122, the oxide layer 124, the lower barrier layer 110, and the substrate SB. The liner layer L3 may cover the liner layer L2. The material of the liner layer L3 includes oxide or nitride, in this embodiment, for example, silicon oxycarbide (SiCO). The material of the liner layer L3 includes oxide or nitride, in this embodiment, for example, silicon oxide. Subsequently, a removal process may be conducted to remove part of the liner layer L2 and part of liner layer L3 located at the top of the bit line structures BL and the bottom of the trench Tr. Following this, the liner layer LA may be formed through a suitable deposition process. The liner layer LA may be conformally formed on the substrate SB. Specifically, the liner layer LA may cover the bit line structures BL, the liner layer L3, and the substrate SB. The material of the liner layer LA includes nitride or oxide, in this embodiment, for example, silicon nitride. Next, a sacrificial layer SAC may be formed through a deposition process, spin coating process, or suitable process. The sacrificial layer SAC is formed on the substrate SB and fills in the trench Tr. The material of the sacrificial layer SAC may include oxide or carbide, in this embodiment, for example, silicon oxide.

Please refer to FIG. 1C. Subsequently, multiple contact window openings NC are formed. In this embodiment, an etching process is conducted to remove the sacrificial layer SAC filled in the trench Tr. Then, the etching process continues to remove the liner layer LA located at the top of the bit line structures BL and the bottom of the trench Tr, to expose part of the substrate SB. Following this, the etching process continues to remove the exposed part of the substrate SB, forming multiple contact window openings NC. In one embodiment, part of the isolation structures IS in the substrate SB are also removed in this etching process.

It is worth noting that after forming multiple contact window openings NC, a capacitor contact window (not shown) may be subsequently formed therein, but this disclosure is not limited to this.

At this point, the manufacturing method of a memory structure 10 in this embodiment is completed. In this embodiment, the bit line contact window 122 is formed above the substrate SB and is not embedded in the substrate SB. The sidewalls of the bit line contact window 122 are covered by the liner layer L2, the liner layer L3, and the liner layer L4. Therefore, after removing the liner layer LA at the bottom of the trench Tr, and then continuing to remove the exposed part of the substrate SB in the trench Tr to form the contact window openings NC, the contact window openings NC may not expose the sidewalls of the bit line contact window 122. This may reduce the risk of short circuits occurring between subsequently formed capacitor contact window (not shown) and the bit line contact window 122. Furthermore, this may allow the contact window openings NC to have more expansion space, removing more of the substrate SB to increase the exposed surface area of the substrate SB, enhancing the contact area between the substrate SB and subsequently formed capacitor contact window (not shown), and improving the electrical performance of the memory structure 10.

The following briefly introduces the structure of the memory structure 10 of this embodiment with reference to FIG. 1C, but this disclosure is not limited to this. Please refer to FIG. 1C. The memory structure 10 of this embodiment includes a substrate SB, a bottom barrier layer 110, a bit line contact window 122, a top barrier layer 130, a bit line layer 140, a top cover layer 150, and a liner layer L1, where the bottom barrier layer 110, the bit line contact window 122, the top barrier layer 130, the bit line layer 140, and the top cover layer 150 are stacked in sequence in the top view direction Z of the substrate SB. In this embodiment, the top barrier layer 130, the bit line layer 140, the top cover layer 150, and the liner layer L1 form the bit line structure BL, but this disclosure is not limited to this.

The substrate SB may include, for example, multiple isolation structures IS and multiple embedded word lines WL. Adjacent isolation structures IS define the active regions AA of the substrate SB. The embedded word lines WL may, for example, extend along direction X and be arranged along direction Y.

The bottom barrier layer 110 may be disposed, for example, on the substrate SB. In this embodiment, the bottom barrier layer 110 overlaps with the active regions AA of the substrate SB in the top view direction Z of the substrate SB, but this disclosure is not limited to this. Between the bottom barrier layer 110 and the embedded word lines WL in the substrate SB, there may be, for example, a distance D in the top view direction Z of the substrate SB. In this embodiment, the distance D is approximately 60 nanometers, but this disclosure is not limited to this. For the remaining introduction of the bottom barrier layer 110, please refer to the above embodiment, which will not be repeated in the following.

The bit line contact window 122 is formed above the substrate SB and may be disposed, for example, on the bottom barrier layer 110, and may be electrically connected to the active regions AA of the substrate SB. In this embodiment, the material of the bit line contact window 122 is selected from metallic materials, for example, tungsten, aluminum, copper, titanium, tantalum, tungsten, niobium, molybdenum, etc. Compared to the known bit line contact windows using non-metallic materials (such as polysilicon), the bit line contact window 122 has a lower sheet resistance, thus may greatly reduce the impedance value of the memory structure 10. Additionally, in this embodiment, since the bit line contact window 122 is not embedded in the substrate SB, the distance between the bit line contact window 122 and the embedded word lines WL in the substrate SB (or the distance D between the bottom barrier layer 110 and the embedded word lines WL) may be relatively increased, which may increase the signal integrity of the memory structure 10, and may reduce the occurrence of crosstalk in the memory structure 10, and may reduce the capacitive load of the memory structure 10.

The bit line structure BL is disposed on the bit line contact window 122. In this embodiment, the bit line structure BL includes a top barrier layer 130, a bit line layer 140, a top cover layer 150, and a liner layer L1. The top barrier layer 130 is disposed on the bit line contact window 122. The bit line layer 140 is disposed on the top barrier layer 130. The top cover layer 150 is disposed on the bit line layer 140. The liner layer L1 is disposed on the top barrier layer 130, the bit line layer 140, and the sidewalls of the top cover layer 150.

The memory structure 10 also includes liner layers L2, L3, and L4. The liner layer L2 is conformally disposed on the liner layer L1, the bit line contact window 122, and the sidewalls of the bottom barrier layer 110. The liner layer L3 is conformally disposed on the sidewalls of the liner layer L2. The liner layer LA is conformally disposed on the sidewalls of the liner layer L3. In this embodiment, the sidewalls of the bit line contact window 122 are covered by the liner layers L2, L3, and L4.

The memory structure 10 also includes multiple contact window openings NC. One of the contact window openings NC may be disposed between adjacent bit line contact windows 122, and exposes part of the substrate SB. In one embodiment, a capacitor contact window (not shown) is disposed in the contact window openings NC. In this embodiment, the bit line contact window 122 is formed above the substrate SB, and the sidewalls of the bit line contact window 122 are covered by the liner layers L2, L3, and L4. Since the bit line contact window 122 is not embedded in the substrate SB, more of the substrate SB may be removed when forming the contact window opening NC, allowing the contact window opening NC to have a larger expansion space in the substrate SB. Consequently, the subsequently formed capacitor contact window (not shown) may have more contact area with the substrate SB, enhancing the electrical performance of the memory structure 10.

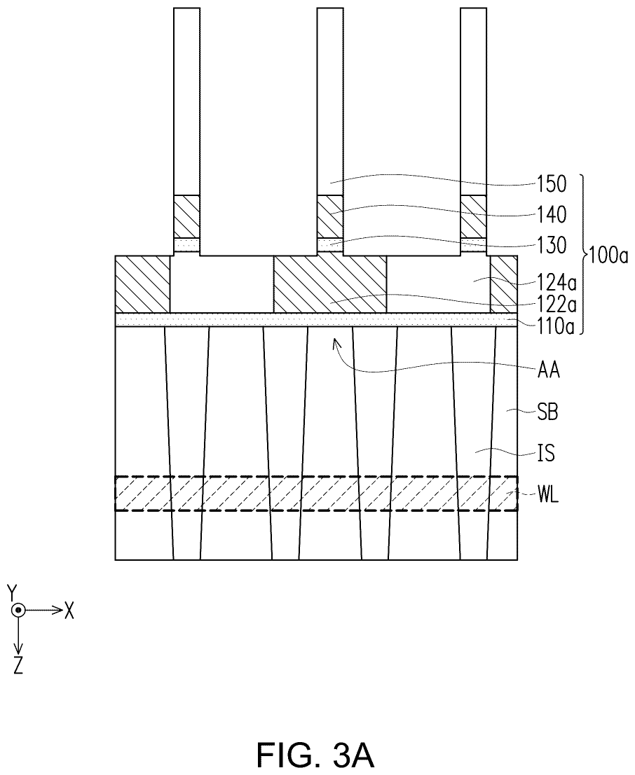

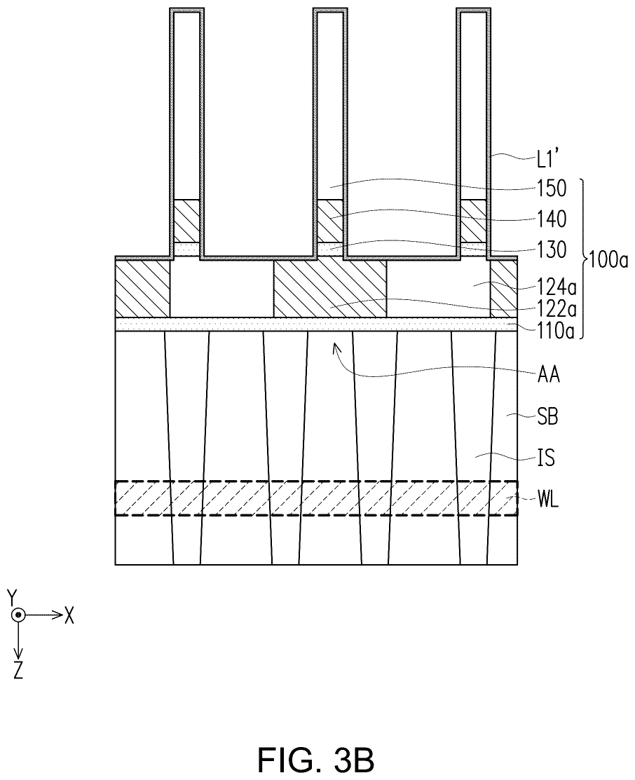

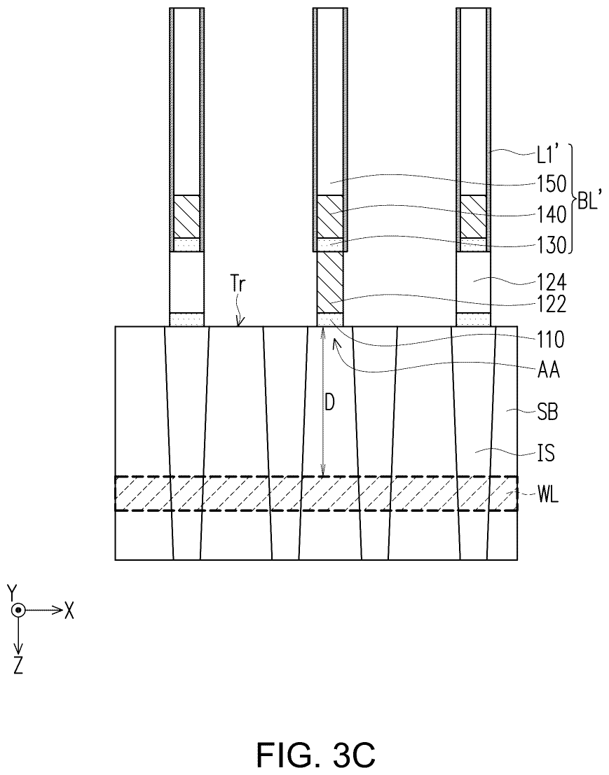

FIG. 3A to FIG. 3C illustrate cross-sectional schematic views of a manufacturing method of a bit line structure according to another embodiment in FIG. 1B. In this embodiment, multiple bit line structures BL′ may be formed through the steps shown in FIG. 3A to FIG. 3C, but the disclosure is not limited to this. The main difference between this embodiment and the embodiment in FIG. 2A to FIG. 2C lies in the formation method of the liner layer L1 (FIG. 2C) and a liner layer L1′ (FIG. 3C). Other related descriptions of this embodiment may refer to the embodiment shown in FIG. 2A to FIG. 2C above, and will not be repeated in the following.

Please refer to FIG. 3A, which provides a structure as shown in FIG. 2A. The detailed formation method may refer to the embodiment shown in FIG. 2A above, and will not be repeated in the following.

Please refer to FIG. 3B, a deposition process is conducted to form a liner layer L1′. In this embodiment, the liner layer L1′ is formed on the top barrier layer 130, the bit line layer 140, and the sidewalls of the top cover layer 150, and is formed on the surfaces of the top cover layer 150 and the exposed bit line contact window material layer 120a. The material of the liner layer L1′ may include oxide and nitride, and in this embodiment, for example, it is silicon oxycarbide. In one embodiment, the deposition process includes a chemical vapor deposition plasma process, but the disclosure is not limited to this.

Please refer to FIG. 3C. An etching process is conducted to remove part of the liner layer L1, part of the bit line contact window material layer 120a, and part of the lower barrier material layer 110a, to form a bit line structure BL', the bit line contact window 122, and the lower barrier layer 110. As shown in FIG. 3C, each bit line structure BL′ includes a top barrier layer 130, a bit line layer 140, and a top cover layer 150 stacked in sequence on the substrate SB, and includes a liner layer L1′ disposed on the top barrier layer 130, the bit line layer 140, and the sidewalls of the top cover layer 150.

Following this, the formation of the contact window openings NC and capacitor contact window (not shown) may continue by referring to the descriptions of FIG. 1B and FIG. 1C.

In summary, in the memory structure and the manufacturing method thereof provided by an embodiment of this disclosure, by forming the bit line contact window above the substrate rather than embedding it in the substrate, and by covering the sidewalls of the bit line contact window with at least one liner layer, when sequentially removing one of the at least one liner layer at the bottom of the trench and part of the substrate to form the contact window opening, the contact window opening will not expose the sidewalls of the bit line contact window. Based on this, the risk of short circuit between the subsequently formed capacitor contact window and the bit line contact window may be reduced. Furthermore, it may allow the contact window opening to have more expansion space, and more of the substrate may be removed to increase its exposed surface area, enhancing the contact area between the substrate and the subsequently formed capacitor contact window. This may improve the electrical performance of the memory structure provided by an embodiment of this disclosure.

Moreover, since the bit line contact window is formed above the substrate rather than embedded in the substrate, the distance between the bit line contact window and the embedded word line in the substrate (or the distance between the lower barrier layer and the embedded word line) may be relatively increased. This may enhance the signal integrity of the memory structure, reduce the occurrence of crosstalk in the memory structure, and decrease the capacitive load of the memory structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A memory structure, comprising:
a substrate, comprising a plurality of active regions;
a bottom barrier layer, disposed on the substrate, and overlapping with one of the active regions in a top view direction of the substrate;
a bit line contact window, formed above the substrate and disposed on the bottom barrier layer, and electrically connected with the one of the active regions;
a bit line structure, disposed on the bit line contact window, and comprising:
a top barrier layer;
a bit line layer, disposed on the top barrier layer;
a top cover layer, disposed on the bit line layer; and
a first liner layer, disposed on the top barrier layer, the bit line layer, and sidewalls of the top cover layer,
a second liner layer, disposed on sidewalls of the first liner layer, the bit line contact window, and the bottom barrier layer;
a third liner layer, disposed on a sidewall of the second liner layer; and
a fourth liner layer, disposed on the substrate, and covering the third liner layer, the bit line structure, and the substrate,
wherein the sidewall of the bit line contact window is covered by the second liner layer, the third liner layer, and the fourth liner layer,
wherein a material of the bit line contact window comprises tungsten,
wherein a material of the first liner layer comprises oxide.

2. The memory structure according to claim 1, wherein the bit line contact window has a rectangular shape in a direction perpendicular to the top view direction of the substrate.

3. The memory structure according to claim 1, wherein the material of the first liner layer comprises silicon oxide or silicon oxycarbide.

4. The memory structure according to claim 1, further comprising a plurality of contact window openings, wherein one of the contact window openings is disposed between adjacent bit line contact windows.

5. (canceled)

6. A manufacturing method of a memory structure, comprising:
forming a stack material layer on a substrate, wherein the stack material layer comprises a bottom barrier material layer, a bit line contact window material layer, a top barrier material layer, a bit line material layer, and a top cover material layer stacked in sequence;
performing a patterning process and an oxide layer growth process on the stack material layer to form a plurality of bit line structures, a bit line contact window, and a bottom barrier layer, wherein one of the bit line structures comprises a top barrier layer, a bit line layer, and a top cover layer stacked in sequence, and comprises a first liner layer disposed on the top barrier layer, the bit line layer, and sidewalls of the top cover layer; and
forming a plurality of contact window openings.

7. The manufacturing method of the memory structure according to claim 6, wherein performing the patterning process on the stack material layer comprises:
conducting a first etching process to remove a part of the top cover material layer, a part of the bit line material layer, and a part of the top barrier material layer to expose a part of the bit line contact window material layer, to form the top barrier layer, the bit line layer, and the top cover layer respectively; and
conducting a second etching process to remove the part of the bit line contact window material layer and a part of the bottom barrier material layer, to form the bit line contact window and the bottom barrier layer respectively.

8. The manufacturing method of the memory structure according to claim 7, wherein the oxide layer growth process is conducted between the first etching process and the second etching process.

9. The manufacturing method of the memory structure according to claim 6, wherein the first liner layer is formed through conducting the oxide layer growth process, and the oxide layer growth process comprises an in-situ plasma process or a chemical vapor deposition process.

10. The manufacturing method of the memory structure according to claim 6, wherein after forming the bit line contact window and the bottom barrier layer, a second liner layer, a third liner layer, and a fourth liner layer are formed in sequence on the substrate, wherein sidewalls of the bit line contact window are covered by the second liner layer, the third liner layer, and the fourth liner layer.
